(19) United States
(12) Patent Application Publication
(10) Pub. No.: US 2016/0295692 A1
(43) Pub. Date: Oct. 6, 2016

(54) PRINTED WIRING BOARD AND METHOD FOR MANUFACTURING THE SAME

(71) Applicant: IBIDEN CO., LTD., Ogaki-shi (JP)

(72) Inventors: Koji ASANO, Ogaki-shi (JP); Takema Adachi, Ogaki-shi (JP)

(73) Assignee: IBIDEN CO., LTD., Ogaki-shi (JP)

(21) Appl. No.: 15/084,165

(22) Filed: Mar. 29, 2016

(30) Foreign Application Priority Data
Apr. 2, 2015 (JP) 2015-076240

(51) Int. Cl. H05K 1/02; H05K 3/40; H05K 3/46; H05K 3/02; H05K 1/03; H05K 1/11

(52) U.S. Cl. CPC H05K 1/0298; H05K 1/0313; H05K 1/112; H05K 3/4652; H05K 3/027; H05K 3/4038; H05K 2201/09045

(57) ABSTRACT

A printed wiring board includes a core substrate, and a first build-up wiring layer formed on the core substrate and including a wiring layer such that the wiring layer includes a resin insulating layer and a conductor layer laminated on the resin insulating layer. The first build-up wiring layer is formed on a first surface of the core substrate such that the first build-up wiring layer forms a high-rise region and a low-rise region with respect to a lamination direction, the first build-up wiring layer includes electrodes positioned to connect an electronic component to the first build-up wiring layer, and the first build-up wiring layer is formed such that the low-rise region is extending in two or more directions from the high-rise region to edges of the core substrate.

### CROSS-REFERENCE TO RELATED APPLICATIONS

The present application is based upon and claims the benefit of priority to Japanese Patent Application No. 2015-076240, filed Apr. 2, 2015, the entire contents of which are incorporated herein by reference.

### BACKGROUND OF THE INVENTION

1. Field of the Invention

The present invention relates to a printed wiring board that has a low-rise region and a high-rise region, electrodes being formed in the high-rise region, and relates to a method for manufacturing the printed wiring board.

2. Description of Background Art

Japanese Translation of PCT International Application Publication No. 2013-520007 describes a method for manufacturing a printed circuit board and a printed circuit board manufactured using the method. The printed circuit board of Japanese Translation of PCT International Application Publication No. 2013-520007 includes a base circuit board that has an internal circuit layer, and has an external circuit layer on the base circuit board. The printed circuit board of Japanese Translation of PCT International Application Publication No. 2013-520007 has a cavity region that is formed by removing the external circuit layer. The entire contents of this publication are incorporated herein by reference.

### SUMMARY OF THE INVENTION

According to one aspect of the present invention, a printed wiring board includes a core substrate, and a first build-up wiring layer formed on the core substrate and including a wiring layer such that the wiring layer includes a resin insulating layer and a conductor layer laminated on the resin insulating layer. The first build-up wiring layer is formed on a first surface of the core substrate such that the first build-up wiring layer forms a high-rise region and a low-rise region with respect to a lamination direction, the first build-up wiring layer includes electrodes positioned to connect an electronic component to the first build-up wiring layer, and the first build-up wiring layer is formed such that the low-rise region is extending in two or more directions from the high-rise region to edges of the core substrate.

According to another aspect of the present invention, a method for manufacturing a printed wiring board includes preparing a core substrate including a first conductor layer and a second conductor layer on the opposite side with respect to the first conductor layer, forming on a first surface of the core substrate a first build-up wiring layer including a wiring layer such that the wiring layer includes a resin insulating layer and a conductor layer laminated on the resin insulating layer, and removing one or more portions of the first build-up wiring layer such that the first build-up wiring layer forms a high-rise region and a low-rise region with respect to a lamination direction. The forming of the first build-up wiring layer includes forming electrodes such that the electrodes are positioned to connect an electronic component to the first build-up wiring layer, and the removing of one or more portions of the first build-up wiring layer includes forming the low-rise region such that the low-rise region is extending in two or more directions from the high-rise region to edges of the core substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a plan view of a printed wiring board according to an embodiment of the present invention;

FIG. 1B is a cross-sectional view for describing the printed wiring board illustrated in FIG. 1A;

FIG. 2A illustrates an example of positions of a high-rise region and a low-rise region;

FIG. 2B illustrates another example of positions of a high-rise region and a low-rise region;

FIG. 2C illustrates another example of positions of a high-rise region and a low-rise region;

FIG. 2D illustrates another example of positions of a high-rise region and a low-rise region;

FIG. 3A illustrates a method for manufacturing a printed wiring board according to an embodiment of the present invention;

FIG. 3B illustrates the method for manufacturing the printed wiring board according to the embodiment of the present invention;

FIG. 3C illustrates the method for manufacturing the printed wiring board according to the embodiment of the present invention;

FIG. 3D illustrates the method for manufacturing the printed wiring board according to the embodiment of the present invention;

FIG. 3E illustrates the method for manufacturing the printed wiring board according to the embodiment of the present invention;

FIG. 3F illustrates the method for manufacturing the printed wiring board according to the embodiment of the present invention;

FIG. 3G illustrates the method for manufacturing the printed wiring board according to the embodiment of the present invention;

FIG. 3H illustrates the method for manufacturing the printed wiring board according to the embodiment of the present invention;

FIG. 3I illustrates the method for manufacturing the printed wiring board according to the embodiment of the present invention;

FIG. 3J illustrates the method for manufacturing the printed wiring board according to the embodiment of the present invention;

FIG. 4 illustrates an example of a connection pad; and

FIG. 5 is a cross-sectional view for describing a printed wiring board according to another embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

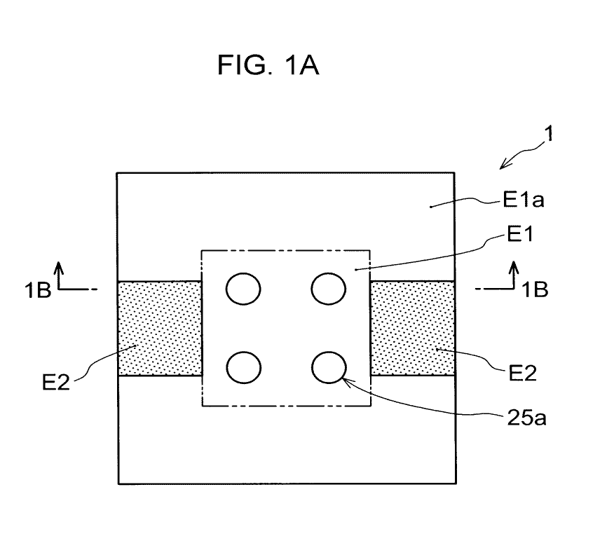

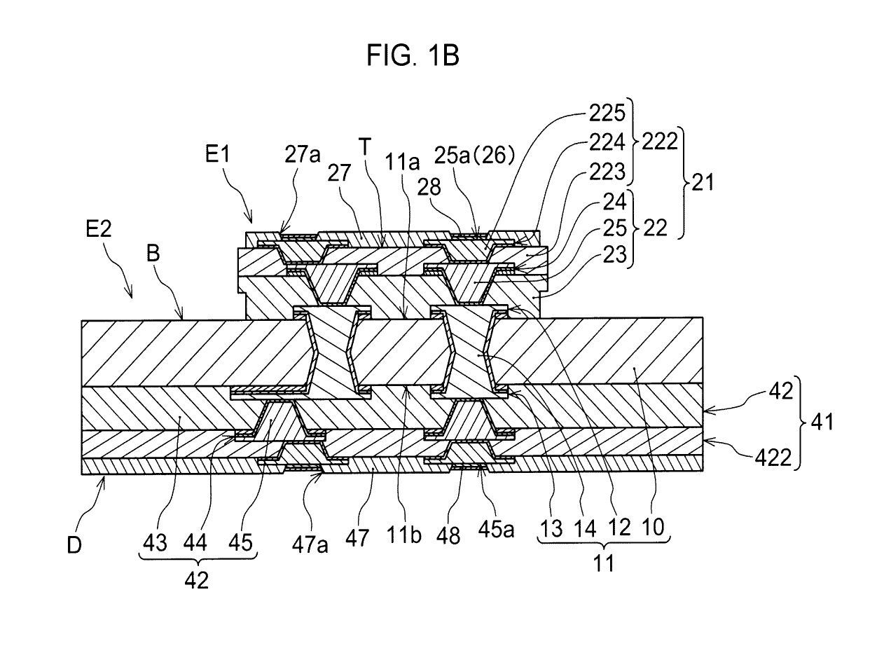

FIG. 1A illustrates a plan view of a printed wiring board 1 of the embodiment. FIG. 1B describes a 1B-1B cross section of FIG. 1A. The printed wiring board 1 includes a core substrate 11 that has a first surface (11a) and a second surface (11b) that is on an opposite side of the first surface (11a), and a build-up wiring structure that is formed on the first surface (11a) of the core substrate 11 and has a first build-up wiring layer 21. The printed wiring board 1 of the embodiment further includes a second build-up wiring layer 41 that is formed on the second surface (11b) of the core substrate. The first build-up wiring layer 21 includes a first wiring layer 22 in which a resin insulating layer 23 and a conductor layer 24 are laminated. As illustrated in FIG. 1A, the printed wiring board 1 includes a high-rise region (E1) that is formed in a middle portion of the printed wiring board 1 and has a high height in a lamination direction of the first build-up wiring layer 21, and a low-rise region (E2) that is formed in each of at least two directions around the high-rise region (E1) and has a height in the lamination direction lower than that of the high-rise region (E1). A region other than the low-rise region (E2) around the high-rise region (E1) is a high-rise part (E1a) that has substantially the same height as the high-rise region (E1). Here, the middle portion does not mean a center portion of a planar shape of the build-up wiring structure, but means a region on a center side relative to an edge portion of the build-up wiring structure. In FIG. 1A, a dot pattern is drawn in the low-rise region (E2). The first build-up wiring layer 21 has an upper surface (T). As illustrated in FIG. 1B, the high-rise region (E1) has pads (25a) on the upper surface (T) of the first build-up wiring layer 21. An electronic component or another wiring board is connected to the pads (25a). The pads (25a) form electrodes 26 for connecting to an electronic component or another wiring board. In the printed wiring board 1, an electronic component can be directly mounted in a region that protrudes as the high-rise region (E1) in the middle portion of the build-up wiring structure. Since an electronic component is directly connected to the wiring layer in the build-up wiring structure, stable connection between the electronic component and the printed wiring board 1 can be obtained.

The low-rise region (E2) extends to an edge of the build-up wiring structure. That is, at least one side of the low-rise region (E2) coincides with an edge of the printed wiring board 1. Another electronic component can be positioned on an exposed surface (B) of the low-rise region (E2). By mounting an electronic component in the low-rise region (E2), in a state in which the electronic component is mounted, an overall thickness of the electronic component and the printed wiring board 1 can be reduced. An electronic component positioned in the low-rise region (E2) and an electronic component positioned in the high-rise region (E1) can be directly connected to each other. Space saving in a semiconductor package is achieved, and yield in mounting electronic components can be improved.

Examples of an electronic component include a semiconductor element, a passive element (such as a capacitor or a resistor), an interposer having a wiring layer, a semiconductor element having a rewiring layer, a WLP (Wafer Level Packages), and the like.

As illustrated in FIG. 1A, it is preferable that the pads (25a) be formed concentrated in substantially middle of the printed wiring board 1. In FIG. 1A, as an example, only four pads (25a) are illustrated. However, in practice, a much larger number of pads (25a) can be formed. An electronic component can be mounted on the high-rise region (E1) via the pads (25a). Other connection pads may be formed in the high-rise part (E1a) around the high-rise region (E1).

As illustrated in FIG. 1B, a first conductor layer 12 is formed on a surface on one side of the core substrate 11, and a second conductor layer 13 is formed on a surface on an opposite side of the first conductor layer 12. The core substrate 11 has a resin insulating layer 10 and through-hole conductors 14 that penetrate the resin insulating layer 10 and connect the first conductor layer 12 and the second conductor layer 13. A cross-sectional shape of each of the through-hole conductors 14 may be an hourglass shape as illustrated in FIG. 1B, but is not particularly limited.

The first wiring layer 22 of the first build-up wiring layer 21 is provided on the first surface (11a) of the core substrate 11. The upper surface (T) of the first build-up wiring layer 21 that has the first wiring layer 22 is a surface on an opposite side of the core substrate 11 side.

The first resin insulating layer 23 of the first wiring layer 22 is formed on the first surface (11a) of the core substrate 11 and on the first conductor layer 12. The conductor layer 24 is formed on the first resin insulating layer 23. The first wiring layer 22 has first via conductors 25 that penetrate the first resin insulating layer 23. The first via conductors 25 connect the first conductor layer 12 and the conductor layer 24.

As illustrated in FIG. 1B, the printed wiring board 1 has a first solder resist layer 27 on the upper surface (T) of the first build-up wiring layer 21, opening portions (27a) being provided in the first solder resist layer 27. The pads (25a) for connecting to an electronic component or another wiring board are respectively exposed by the opening portions (27a). As illustrated in FIG. 1B, the first solder resist layer 27 covers substantially the entire upper surface (T) of the high-rise region (E1) of the build-up wiring structure. Although not illustrated in the drawings, the first solder resist layer 27 may also cover an upper surface of the high-rise part (E1a). In the example illustrated in FIG. 1B, the exposed surface (B) of the low-rise region (E2) of the build-up wiring structure is a surface of the resin insulating layer 10 that is exposed in a region other than the high-rise region (E1) and the high-rise part (E1a).

That is, in the example of FIG. 1B, the printed wiring board 1 has the connection pads (25a) on the upper surface (T) of the high-rise region (E1) of the first build-up wiring layer 21, but does not have connection pads on the exposed surface (B) of the low-rise region (E2). An electronic component is mounted on the upper surface (T) of the high-rise region (E1) via the pads (25a). In the printed wiring board 1 according to an embodiment of the present invention, an electronic component such as a semiconductor element that is mounted in the high-rise region (E1) is directly connected to the build-up wiring structure of the printed wiring board 1. Therefore, connection reliability between the electronic component and the printed wiring board is high.

The first build-up wiring layer 21 has at least one wiring layer. The first build-up wiring layer 21 may have two or more wiring layers. As illustrated in FIG. 1, a second wiring layer 222 that includes a second resin insulating layer 223 and a conductor layer 224 may be formed on the first wiring layer 22. In this case, the second resin insulating layer 223 is formed on the first resin insulating layer 23 and the conductor layer 24. The conductor layer 224 is formed on the second resin insulating layer 223. The conductor layer 24 and the conductor layer 224 are connected by second via conductors 225 that penetrate the second resin insulating layer 223.

Further, as illustrated in FIG. 5, the first build-up wiring layer 21 may include an additional wiring layer. In this example, the first build-up wiring layer 21 further has a third wiring layer 322 on the second wiring layer 222. A third resin insulating layer 323 and a conductor layer 324 on the third resin insulating layer 323 are formed. The conductor layer 224 and the conductor layer 324 are connected by third via conductors 325 that penetrate the, third resin insulating layer 323.

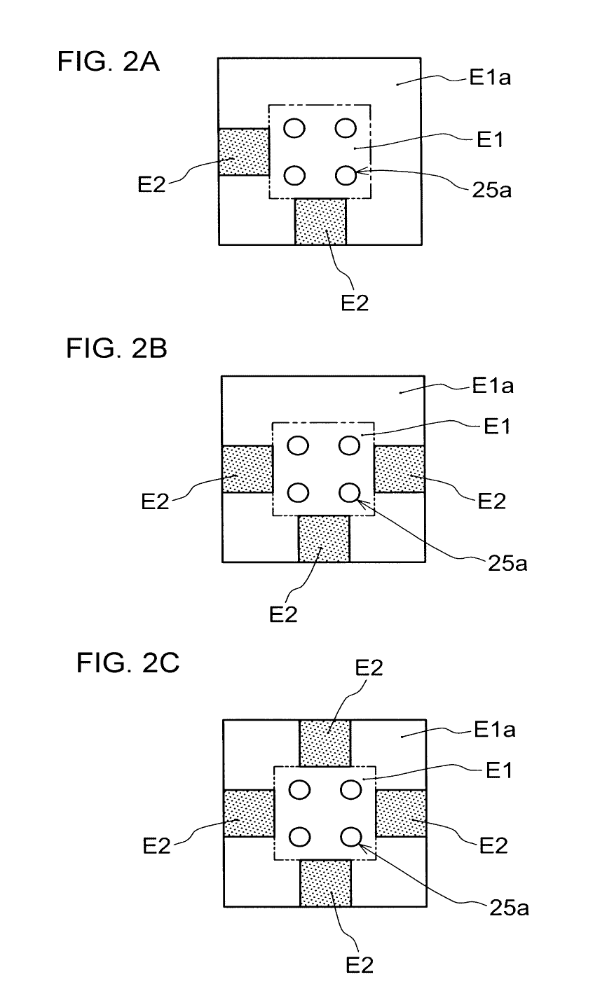

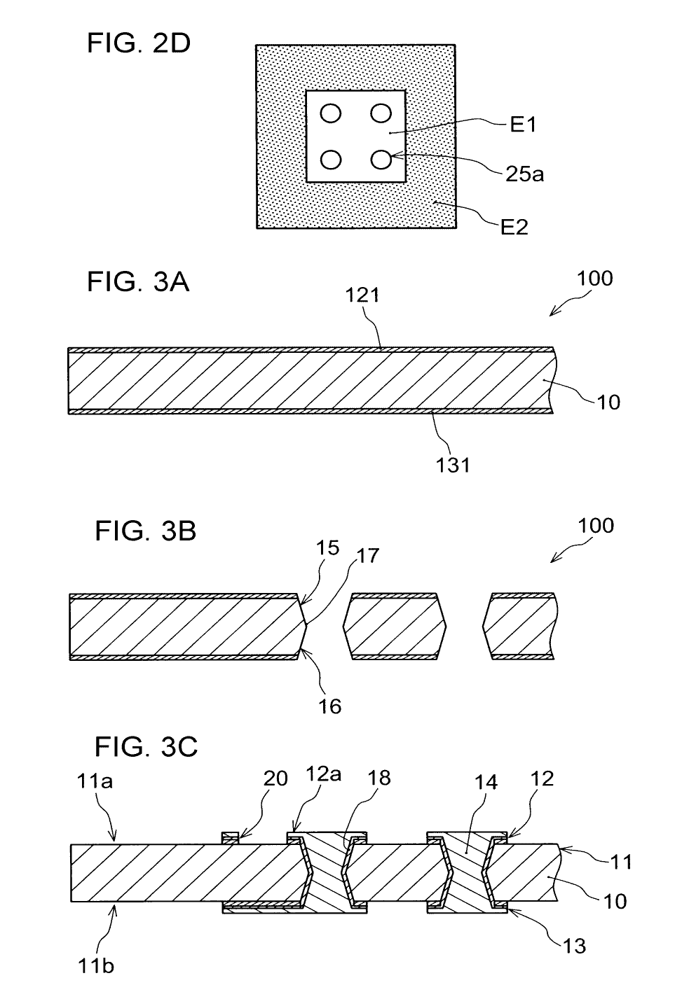

As illustrated in FIG. 1A, the pads (25a) are formed on the conductor layer 224, which is an uppermost layer of the first build-up wiring layer 21. The electrodes 26 for connecting to an electronic component are formed by the pads (25a). The pads (25a) are formed concentrated the high-rise region (E1) of the first build-up wiring layer 21, that is, preferably in the middle portion of the printed wiring board 1. However, other pads may be formed to form electrodes also in a high-rise part (E1a) around the high-rise region (E1). The low-rise region (E2), which has a lower height in the lamination direction as compared to the high-rise region (E1), is formed in each of two directions around the high-rise region (E1). Various examples of the high-rise region (E1) and the low-rise region (E2) of the printed wiring board 1 are illustrated in FIGS. 1A and 2A-2D. In these drawings, only four electrodes 26 are illustrated. However, this is for simplifying the drawings. In practice, a large number of the electrodes 26 are formed and are connected to an electronic component that is mounted in the high-rise region (E1).

A first example is illustrated in FIG. 1A. In FIG. 1A, two low-rise regions (E2) are separately formed at positions opposing each other across the high-rise region (E1). The low-rise regions (E2) are each formed by removing a portion of the build-up wiring structure. Each of the low-rise regions (E2) extends from one side of the high-rise region (E1) to an edge of the build-up wiring structure. The low-rise regions (E2) illustrated in FIG. 1A are each formed by removing a portion of the build-up wiring structure in a region extending from one side of the high-rise region (E1) to an edge on an outer peripheral side. The reference numeral symbol “E1a” does not indicate a part of the high-rise region (E1) on which the pads (25a) are exposed, but indicate a high-rise part that has the same height as the high-rise region (E1).

Other examples are respectively illustrated in FIG. 2A-2D. In FIG. 2A, two low-rise regions (E2) are separately formed in two directions around the high-rise region (E1) and each extend to an edge of the build-up wiring structure. FIG. 2A illustrates an example in which the two low-rise regions (E2) are formed in two directions that form an angle of 90 degrees around the high-rise region (E1). In FIG. 2B, three low-rise regions (E2) are separately formed. In FIG. 2C, at positions 90 degrees apart from the pair of the low-rise regions (E2) illustrated in FIG. 1A, another pair of low-rise regions (E2) are further formed across the high-rise region (E1). In all of the examples illustrated in FIG. 2A-2C, the low-rise regions (E2) each extend to an edge of the build-up wiring structure. That is, at least one side of each of the low-rise regions (E2) coincides with an edge of the printed wiring board 1. In the examples illustrated in FIGS. 1A and 2A-2C, the printed wiring board 1 has multiple low-rise regions (E2) and, for example, different electronic components may be respectively positioned on the low-rise regions (E2). Or, some or all of the electronic components that are positioned in the low-rise regions (E2) may be of the same type. Positions and sizes of two low-rise regions (E2) are not limited to the examples illustrated in FIGS. 1A and 2A-2C, but can be suitably designed according to sizes and types of the electronic components to be positioned in the low-rise regions (E2). Further, it is also possible that a contour of a portion of each the low-rise regions (E2) other than the side defined by the edge of the build-up wiring structure is not formed by a linear or substantially right-angled corner part. Each low-rise region (E2) has a shape that is suitably designed according to an electronic component to be positioned in the low-rise region (E2).

Further, a low-rise region (E2) is formed in each of at least two directions around the high-rise region (E1). In addition to the electrodes 26 that are formed in the high-rise region (E1), other electrodes (26a) may be formed in the high-rise part (E1a). The other electrodes (26a) can be provided according to positioning of electrodes of an electronic component or another wiring board to be mounted on the high-rise region (E1).

In FIGS. 1A and 2A-2C, the examples are illustrated in which only one side of each of the low-rise regions (E2) coincides with an edge of the printed wiring board 1. However, the low-rise regions (E2) may also be formed so as to each extend to edges of the build-up wiring structure in two or three directions. That is, it is also possible that the low-rise regions (E2) are formed such that two or three sides of each of the low-rise regions (E2) coincide with edges of the printed wiring board 1. Further, it is also possible that, of each of the four low-rise regions (E2) illustrated in FIG. 2C, the two sides that do not coincide with edges of the printed wiring board 1 or the high-rise region (E1) are respectively extended to edges of the build-up wiring structure so that adjacent low-rise regions (E2) are joined to each other. That is, it is also possible that a low-rise region (E2) is formed over the entire outer periphery of the high-rise region (E1) in a manner surrounding the high-rise region (E1). This example is illustrated in FIG. 2D. Low-rise regions (E2) in various formations and numbers as illustrated in these examples can be easily formed by changing positions and sizes of removed portions of the build-up wiring structure.

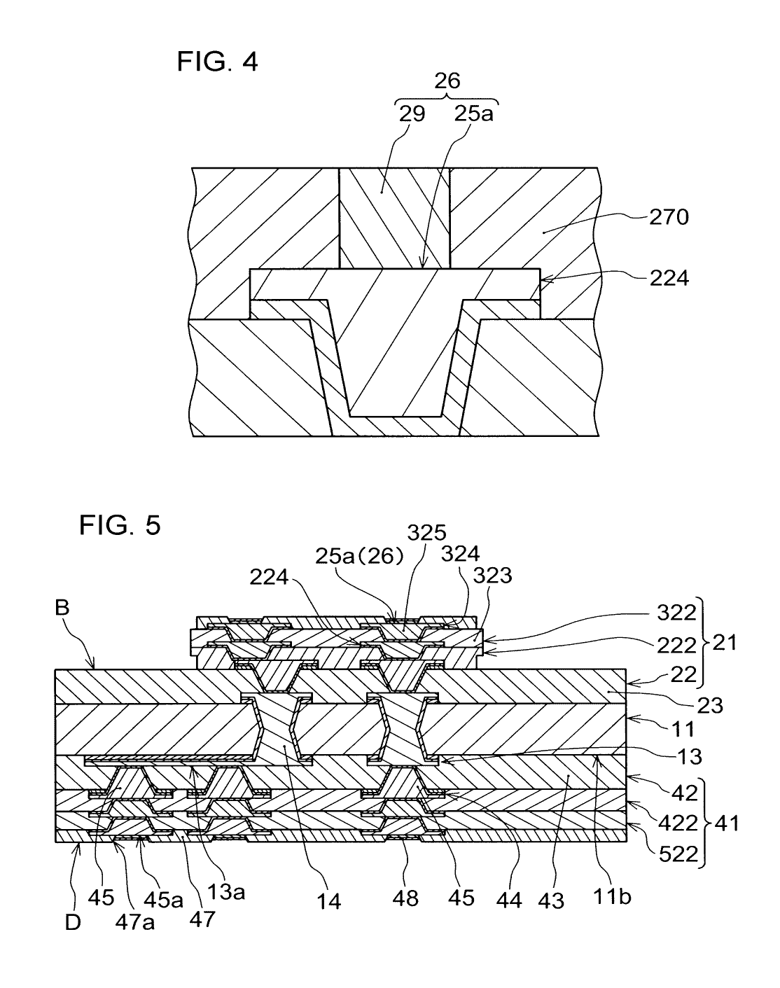

A protective film 28 may be formed on each of the pads (25a). Further, as illustrated in FIG. 4, conductor posts 29 for connecting to an electronic component or another wiring board may be formed on the pads (25a). As illustrated in FIG. 4, the conductor posts 29 are columnar conductors that protrude from the conductor layer 224, and can be formed by forming an electrolytic plating film on each of the pads (25a). The electrodes 26 are formed by the connection pads (25a) and the conductor posts 29. In FIG. 4, side surfaces of the conductor posts 29 are covered by a mold resin 270 such as epoxy, not the solder resist layer 27 of the FIG. 1B. The mold resin layer 270 can be formed by laminating a resin material in a shape of a sheet or the like on the conductor posts 29, melting the resin material by applying heat so as to cover the side surfaces of the conductor posts 29, and curing the resin material by cooling. FIG. 4 illustrates an example in which the conductor posts 29 are formed to have substantially the same height as that of the mold resin layer 270. The conductor posts 29 may also be formed to have a height higher than that of the mold resin layer 270. A distance between an electronic component that is mounted on the high-rise region (E1) and the printed wiring board 1 is widened, and a stress that can occur due to a difference in thermal expansion coefficient between the printed wiring board 1 and the electronic component that is mounted on the high-rise region (E1) in an upper portion can be absorbed by the conductor posts 29. Further, it is also possible that the conductor posts 29 are formed to have a lower height than that of the mold resin layer 270 and be recessed relative to a surface of the mold resin layer 270. In connecting to an electronic component that is mounted in the high-rise region (E1), a portion of the mold resin layer 270 becomes a wall, and an electrical short circuiting state, in which bonding members or the like become in contact with each other between adjacent electrodes 26 or the like, can be prevented.

The low-rise regions (E2) are each formed by removing a portion of the build-up wiring structure. A portion of the build-up wiring structure in a place where a low-rise region (E2) is formed is removed after the build-up wiring structure is formed. In forming a low-rise region (E2) in the present embodiment, for example, an upper portion and its vicinity (where a wiring density is likely to be low in general) of the build-up wiring structure near the upper surface (T) away from the core substrate can be used as a region for forming the low-rise region (E2). Further, the region for forming a low-rise region (E2) is not limited to an upper portion of the build-up wiring structure. Any region of the build-up wiring structure that does not interfere with formation of a wiring pattern can be a to-be-removed region for forming a low-rise region (E2). Then, a low-rise region (E2) is formed by removing a to-be-removed region, and an electronic component can be positioned on the low-rise region (E2). Therefore, an electronic component can be efficiently positioned. The printed wiring board can be easily designed.

In the printed wiring board 1, an electronic component such as a semiconductor element is mounted on the upper surface (T) of the high-rise region (E1), and further another electronic component can be accommodated in a low-rise region (E2). An area of the upper surface (T) of the high-rise region (E1) is not required to match a bottom surface area of an electronic component to be mounted on the high-rise region (E1). The bottom surface area of the electronic component to be mounted on the high-rise region (E1) may be larger than the area of the upper surface (T) of the high-rise region (E1), and the electronic component to be mounted may extend beyond an edge of the high-rise region (E1) to a point above a high-rise part (E1a), and may protrude from the edge of the high-rise region (E1) toward the low-rise region (E2) side. A relatively thin electronic component may be mounted on the upper surface (T) of the high-rise region (E1), and an electronic component having a thickness thicker than the thickness of the electronic component mounted on the high-rise region (E1) may be mounted in the low-rise region (E2). According to such an example, reduction in thickness of the printed wiring board including the electronic components can be achieved.

An electronic component positioned on the low-rise region (E2) and an electronic component mounted on the high-rise region (E1) can be connected to each other. The electronic component on the low-rise region (E2) can be connected to the exposed surface (B) of the low-rise region (E2) via a bonding member via a surface on an opposite side of a surface opposing the electronic component mounted on the high-rise region (E1). As the bonding member, for example, an insulating paste or DAF or the like is used. A depth of the low-rise region (E2) can be designed to match a thickness of the electronic component accommodated in the low-rise region (E2). The thickness of the bonding member may be determined such that a sum of the thickness of the electronic component and the thickness of the bonding member matches the depth of the low-rise region (E2).

The depth of the low-rise region (E2) refers to a difference in the height in the lamination direction between the high-rise region (E1) and the high-rise part (E1a) that are contained in the build-up wiring structure and the low-rise region (E2), that is, a distance from the upper surface (T) of the build-up wiring structure to the exposed surface (B) of the low-rise region (E2). This distance is substantially equal to the height of the removed build-up wiring structure. At least one build-up wiring layer is removed. This distance can be easily changed as appropriate by changing the thicknesses of the wiring layers to be removed and/or the number of the wiring layers to be removed, depending on an intended use of the printed wiring board 1 or according to a size of an electronic component or the like to be mounted on the printed wiring board 1. For example, when the electronic component mounted on the low-rise region (E2) is a memory, the depth of the low-rise region (E2) may be designed to be about 200 μm. For example, in order to form a low-rise region (E2) such that the distance from the upper surface (T) of the build-up wiring structure to the exposed surface (B) of the low-rise region (E2) is about 200 μm, two wiring layers in the build-up wiring structure may be removed.

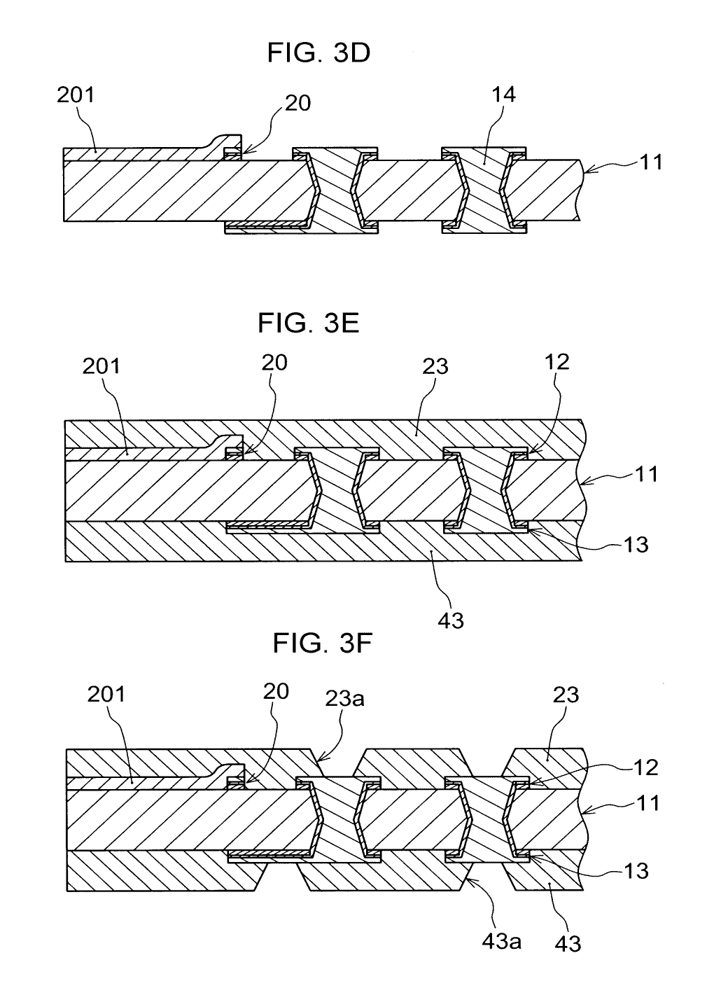

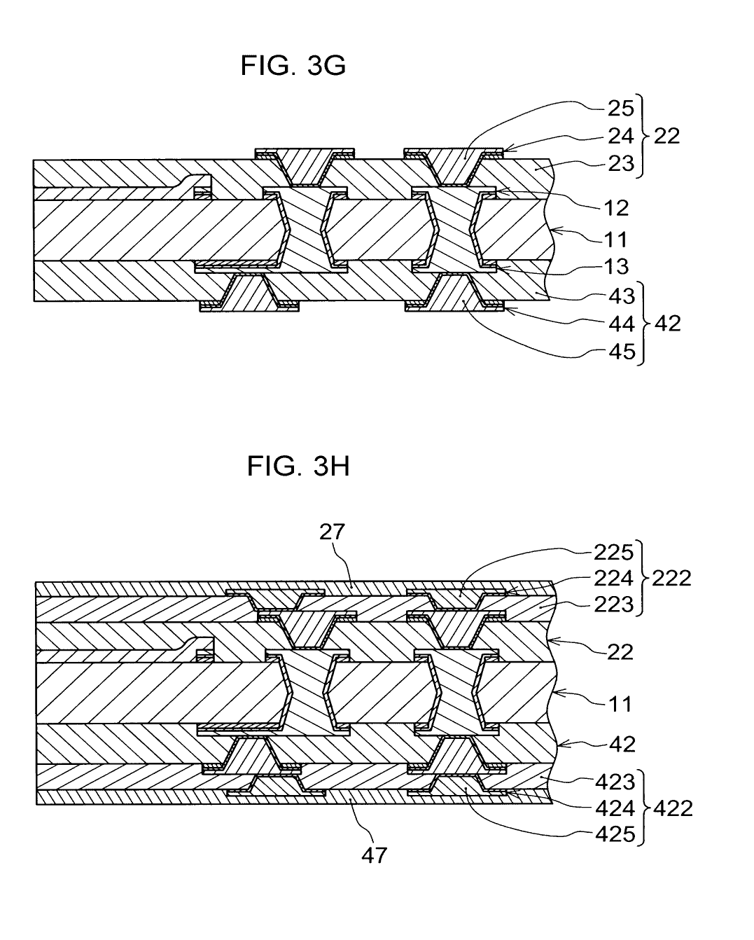

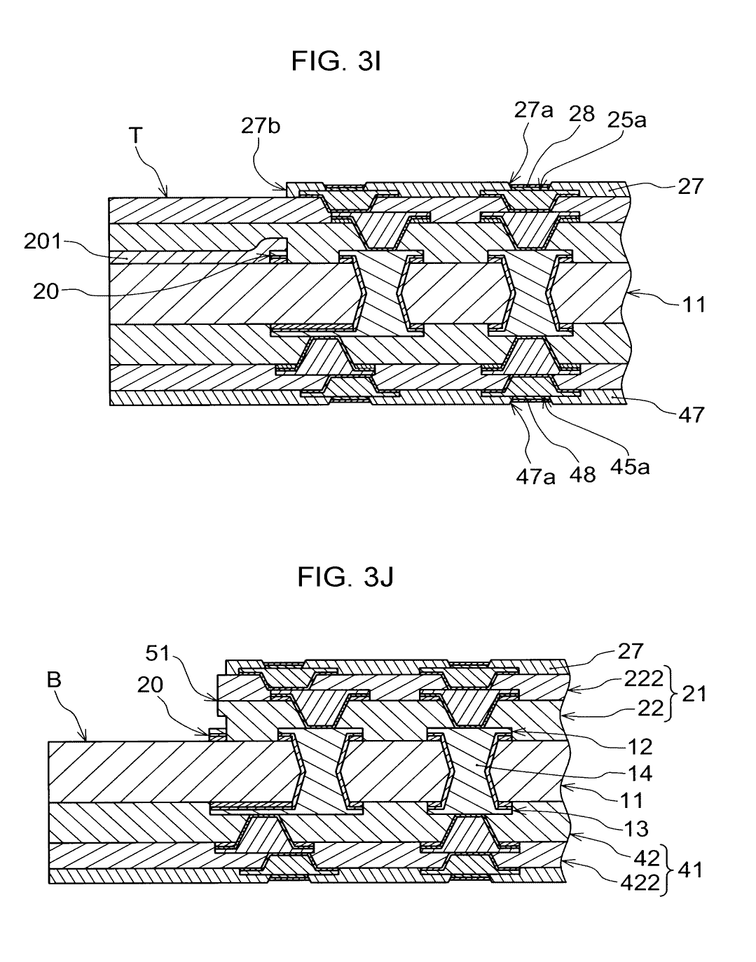

The removal of a portion of the build-up wiring structure is performed, for example, by laminating, in the middle of a lamination process of the build-up wiring structure, a separation film 201 (see FIG. 3D) at a place where a low-rise region (E2) is to be formed and, after the lamination of the build-up wiring structure, removing one or two or more wiring layers of the build-up wiring structure together with the separation film 201, the wiring layers being positioned above the separation film 201. As the separation film 201, for example, a film can be used that can be in close contact with but does not bond to resin insulating layers between which the separation film 201 is laminated. For example, the separation film 201 is formed from a resin material such as polyimide. For example, the separation film 201 may be formed in advance into a film of a predetermined shape and then laminated on a resin insulating layer during the lamination process of the build-up wiring structure. The separation film 201 may also be formed by supplying a liquid resin material on a resin insulating layer. Due to the releasability of the separation film 201 from a resin insulating layer, removal of the separation film 201 and the build-up wiring structure laminated on the separation film 201 can be easily performed under mild conditions. In a removal process of the separation film, a stress applied to the printed wiring board 1 is likely to be reduced. A damage to the printed wiring board 1 is unlikely to occur. Further, it is likely that, as the exposed surface (B) of the low-rise region (E2), rather than a fractured surface, a relatively smooth surface can be obtained.

In the example of FIG. 5, in a manufacturing process of the printed wiring board 1, the separation film 201 is inserted between a portion of the first build-up wiring layer 21 to be removed and the first resin insulating layer 23, which is a lower of the portion to be removed. By removing the build-up wiring structure on the separation film 201 together with the separation film 201, a surface of the first resin insulating layer 23 is exposed. The exposed surface of the first resin insulating layer 23 becomes the exposed surface (B) of the low-rise region (E2). In the example of FIG. 1B, the separation film 201 is inserted between the first wiring layer 22, which is a lowermost layer of a portion of the first build-up wiring layer 21 to be removed, and the core substrate 11, which is a lower layer of the first wiring layer 22. By removing the build-up wiring structure on the separation film 201 together with the separation film, a surface of the resin insulating layer 10 of the core substrate 11 is exposed. The exposed surface of the resin insulating layer 10 becomes the exposed surface (B) of the low-rise region (E2). In the example of FIG. 1A, the exposed surface (B) of the low-rise region (E2) is positioned on the same plane as a boundary surface between the resin insulating layer 10 that forms the core substrate 11 and the build-up wiring structure.

Further, separation films 201 may be respectively laminated at different positions in the lamination direction of the build-up wiring structure at places where low-rise regions (E2) are formed. In such an example, in a removal process of build-up wiring structures on the separation films 201 and the separation films 201, build-up wiring structures of different numbers of layers are respectively removed in the places where the low-rise regions (E2) are formed. As a result, multiple low-rise regions (E2) having mutually different distances from the upper surface (T) of the build-up wiring structure to their exposed surfaces (B) can be formed in the printed wiring board 1.

It is preferable that an end part and a side surface of a via conductor that penetrates a resin insulating layer of a wiring layer in the first build-up wiring layer 21 of the high-rise region (E1) be not exposed on a wall surface of a stepped portion between the high-rise region (E1) and the high-rise part (E1a) and the low-rise region (E2).

In the present embodiment, as in the printed wiring board 1 illustrated in FIG. 1B, in addition to the first build-up wiring layer 21, a build-up wiring layer including at least one wiring layer that is formed by laminating a resin insulating layer and a conductor layer may be formed on the second surface (11b) of the core substrate. In the example illustrated in FIG. 1B, on the second surface (11b) of the core substrate, the second build-up wiring layer 41 is formed that includes a fourth wiring layer 42 and a fifth wiring layer 422 that are each formed by laminating a resin insulating layer and a conductor layer. The fourth wiring layer 42 is provided on the second surface (11b) of the core substrate 11. A resin insulating layer 43 of the fourth wiring layer 42 is formed on the second surface (11b) of the core substrate 11 and on the second conductor layer 13. A conductor layer 44 is formed on the resin insulating layer 43. The fourth wiring layer 42 has fourth via conductors 45 that penetrate the resin insulating layer 43. The fourth via conductors 45 connect the conductor layer 44 and the second conductor layer 13 of the core substrate 11. On the fourth wiring layer 42, similar to the fourth wiring layer 42, the fifth wiring layer 422 is laminated that includes a resin insulating layer, a conductor layer, and via conductors that penetrate the resin insulating layer and connect the conductor layers that are formed above and below the resin insulating layer. The wiring layers of the second build-up wiring layer 41 are connected to the electrodes 26 via the through-hole conductors 14 of the core substrate 11.

The printed wiring board 1 includes a second solder resist layer 47 on an entire lower surface (D) that is a surface on the second build-up wiring layer 41 side. The second solder resist layer 47 is formed on the outermost conductor layer and resin insulating layer of the second build-up wiring layer 41. The second solder resist layer 47 has opening portions (47a). Due to the opening portions (47a), connection pads (45a) are exposed on the lower surface (D) of the printed wiring board 1. The connection pads (45a) are formed in the conductor layer in the fifth wiring layer 422. The connection pads (45a) are, for example, pads for connecting to an electronic component. The connection pads (45a) may be used for connecting to a motherboard or the like. As in the example of FIG. 1B, a protective film 48 may be formed on each of the connection pads (45a).

In the present embodiment, it is also possible that a build-up wiring layer is not formed on the second surface (11b) of the core substrate. In such an example, the second surface (11b) of the core substrate 11 becomes a lower surface of the printed wiring board, and the second solder resist layer 47 may be formed on the second surface (11b). In this case, connection pads may be formed on the second surface (11b) of the core substrate. Further, the number of the wiring layers included in the second build-up wiring layer 41 and the number of the wiring layers included in the first build-up wiring layer 21 may be different from each other.

FIG. 5 illustrates an example in which a sixth wiring layer 522 is further laminated on the fifth wiring layer 422. Similar to the fourth wiring layer 42, the sixth wiring layer 522 includes a resin insulating layer, a conductor layer, and via conductors that penetrate the resin insulating layer and connect the conductor layers that are formed above and below the resin insulating layer. The second solder resist layer 47 is formed on the sixth wiring layer 522. Similar to the example of FIG. 1B, the connection pads (45a) that are exposed in the opening portions (47a) of the second solder resist layer 47 are provided in the conductor layer in the sixth wiring layer 522. As illustrated in FIG. 5, the wiring layers of the second build-up wiring layer 41 may be connected to the electrodes 26 via the through-hole conductors 14 of the core substrate 11. A protective film 28 may be formed on each of the connection pads (45a).

Although electrodes are not formed on the exposed surface (B) of the low-rise region (E2), an inner-layer wiring layer may be formed in the low-rise region (E2). This example is illustrated in FIG. 5. In a portion overlapping with the low-rise region (E2) in a plan view of the second conductor layer 13, a wiring pattern (13a) is formed that connects the through-hole conductors 14 and the fourth via conductors 45. An inner-layer wiring layer is formed in the low-rise region (E2) by the second conductor layer 13. The wiring pattern (13a) electrically connects the pads (25a) and the connection pads (45a) via the through-hole conductors 14, the fourth via conductors 45 and the like. As illustrated in FIG. 5, the connection pads (45a) may be formed on the surface of the second build-up wiring layer 41 below the low-rise region (E2).

An embodiment of a method for manufacturing the printed wiring board 1 is described with reference to FIG. 3A-3J.

The core substrate 11 is prepared (FIG. 3A-3C). The core substrate 11 is formed by the resin insulating layer 10, the first conductor layer 12 and the second conductor layer 13, the first conductor layer 12 and the second conductor layer 13 being respectively laminated on the first surface (11a) and the second surface (11b) of the core substrate 11, the second surface (11b) being on an opposite side of the first surface (11a) (FIG. 3C). The core substrate 11 is formed from a starting substrate 100 that includes the resin insulating layer 10, and a first copper foil 121 and a second copper foil 131 that are respectively laminated on both sides of the resin insulating layer 10 (FIG. 3A). The resin insulating layer 10 has a thickness of, for example, 80 μm-150 μm. The resin insulating layer 10 is formed of inorganic particles, such as silica particles, and a resin. The resin insulating layer 10 may further contain a reinforcing material such as a glass cloth, glass fiber, aramid fiber, or the like. Examples of the resin include an epoxy resin, and a BT (bismaleimide triazine) resin. The resin insulating layer 10 of FIG. 3A is formed of inorganic particles, a reinforcing material and a resin.

Laser is irradiated to the starting substrate 100 from the first copper foil 121 side. First opening portions 15 are formed on the first copper foil 121 side of the starting substrate 100. Further, laser is irradiated to the starting substrate 100 from the second copper foil 131 side. Second opening portions 16 that respectively connect to the first opening portions 15 are formed on the second copper foil 131, and through holes 17 for the through-hole conductors 14 are formed (FIG. 3B). The first opening portions 15 taper from the first copper foil 121 side toward the second copper foil 131 side. The second opening portions 16 taper from the second copper foil 131 side toward the first copper foil 121 side.

An electroless plating film is formed on the first copper foil 121, the second copper foil 131, and side walls of the through holes 17. Thereafter, by electrolytic plating, an electrolytic plating film is formed on the electroless plating film. A plating film 18, which is formed from the electroless plating film and the electrolytic plating film on the electroless plating film, is formed in the through holes 17. At the same time, the plating film 18 is formed on the first surface side of the first copper foil and on the second surface side of the second copper foil. The through holes 17 are filled by the electrolytic plating film, and the through-hole conductors 14 each having a hourglass shape are formed. An etching resist is formed on the plating film 18. The plating film 18, the first copper foil 121 and the second copper foil 131 that are exposed from the etching resist are removed. The etching resist is removed. As illustrated in FIG. 3C, the core substrate 11 having the first surface (11a) and the second surface (11b) that is on an opposite side of the first surface (11a) is prepared. The first conductor layer 12 is formed that includes the first copper foil on the first surface (11a) and the plating film 18 on the first copper foil. The second conductor layer 13 is formed that includes the second copper foil on the second surface (11b) and the plating film 18 on the second copper foil. The through-hole conductors 14 connect the first conductor layer 12 and the second conductor layer 13.

The first conductor layer 12 may include a pattern 20. The pattern 20 is a conductor pattern that can be used for forming the low-rise regions (E2) (see FIG. 1). That is, the pattern 20 can be formed at a peripheral edge part of a place where a low-rise region (E2) is formed so as to surround the place where the low-rise region (E2) is formed. In the printed wiring board 1 of the present embodiment, the low-rise regions (E2) are formed in two directions around the high-rise region (E1) (see FIG. 1). Preferably, the pattern 20 is formed at peripheral edge parts of the respective places where the low-rise regions (E2) are formed. FIG. 3C illustrates an example in which the pattern 20 is not connected to another wiring pattern of the first conductor layer 12 and the through-hole conductors. However, for example, the pattern 20 may be an end part of a pattern (12a) that is a land pattern of the through-hole conductors. The pattern 20 includes a pattern that circles along peripheral edge parts on three sides, among the peripheral edge parts of the place where the low-rise region (E2) is formed, excluding an edge of the printed wiring board 1. The pattern 20, for example, can function as a stopper for laser that is irradiated when the low-rise region (E2) is formed. The low-rise region (E2) is formed such that one side of the low-rise region (E2) coincides with an edge of the printed wiring board 1 that includes the first build-up wiring layer (see FIG. 1B). It is preferable that the pattern 20 be formed to circle along the peripheral edge parts of the place where the low-rise region (E2) is formed and be formed such that two ends of the pattern 20 reach points near an edge of the printed wiring board 1.

Hereafter, in the method illustrated in FIG. 3D-3J for manufacturing the printed wiring board 1, an example is described in which the core substrate 11 (FIG. 3C) is used on which the pattern 20 that is not connected to the through-hole conductors is formed in the process in which the first conductor layer 12 is formed. However, even in the case where the core substrate 11 is used on which the pattern 20 is formed on an end part of the pattern (12a), by performing the same processes as those illustrated by FIG. 3D-3J, the printed wiring board 1 including the low-rise region (E2) can be manufactured.

As illustrated in FIG. 3D, the separation film 201 is laminated on a place of the resin insulating layer 10 on the first surface (11a) side of the core substrate 11, the place being where the low-rise region (E2) is formed. FIG. 3D illustrates an example in which the separation film 201 is laminated so as to completely cover an upper surface of the pattern 20. It is also possible that the separation film 201 is laminated so as to cover only a portion of the pattern 20. Further, it is also possible that the separation film 201 is laminated such that an end surface of the separation film 201 is in contact with a side surface of the pattern 20. The separation film 201 may be laminated such that the separation film 201 reaches at least a point near the pattern 20. At least one side of the separation film 201 extends to a point near an edge of the printed wiring board 1. As described above, the pattern 20 functions as a stopper for laser. The laser, as will be described later, is irradiated for separating a portion that is removed together with the separation film 201 and the other portion when the low-rise region (E2) is formed. When the separation film 201 does not reach the pattern 20, due to irradiation of laser to the pattern 20, there may be a small portion, below which the separation film 201 does not exist, near an outer periphery of a to-be-removed portion that is separated from the other portion. However, there is no problem when the to-be-removed portion is removed without causing an excessive stress to the printed wiring board 1 during processing.

The separation film 201 is, for example, a resin film having substantially the same size as that of the place where the low-rise region (E2). An example of the separation film 201 is a polyimide film. For example, a resin molded into a film-like shape is laminated on and temporarily welded to the resin insulating layer. Or, the lamination of the separation film 201 is performed by applying a liquid or paste-like resin material in a predetermined shape by printing or the like using a screen mask or the like, and by drying or heating when desired. In an example in which a resin that is molded in a film-like shape is used, a film that is router-processed in advance to have substantially the same size as that of the place where the low-rise region (E2) can be used as the separation film 201. Further, it is also possible that a substantially liquid or gel-like resin material is printed on the resin insulating layer using a screen mask or the like, and is solidified and formed in a film-like shape by drying or heating when desired. In this example, for example, a gel-like resin material can be printed on the resin insulating layer so as to cover the place where the low-rise region (E2) is formed. However, the material for forming the separation film 201 and the shape of the separation film 201 are not limited to these examples. Any film can be used as long as it is a film that can be easily removed from a lamination surface of the separation film 201 together with a resin insulating layer or the like that is laminated on the separation film 201. The separation film 201 can have any thickness as long as the separation film 201 does not interfere with the lamination of a resin insulating layer on the separation film 201 and, when the resin material is solidified into a film-like shape, the solidification can be accomplished in a relatively short period of time.

The first wiring layer 22 is laminated on the first surface (11a) of the core substrate 11 (FIG. 3E-3G). The first resin insulating layer 23 of the first wiring layer 22 is formed on the first surface (11a) of the core substrate 11 and on the first conductor layer 12 by hot pressing. The first resin insulating layer 23 contains a resin such as epoxy, and inorganic particles such as silica. The first resin insulating layer 23 may further include a reinforcing material such as a glass cloth. However, from a point of view of facilitating the formation of the low-rise region (E2), it may be preferable to not include a reinforcing material. When the first resin insulating layer 23 is formed, a metal foil may be laminated together with the resin material that forms the first resin insulating layer 23 on a side of the first resin insulating layer 23 opposite to the core substrate 11 side. Even when there is unevenness partially due to the thickness of the separation film 201, pressing can be performed with a uniform pressure.

As illustrated in FIG. 3F, openings (23a) for the first via conductors 25 reaching the first conductor layer 12 are formed in the first resin insulating layer 23. For example, the conductor layer 24 is formed using a semi-additive method. A metal coating is formed on the first resin insulating layer 23 and in the openings (23a) using electroless plating, sputtering, or the like. A plating resist film is formed on the metal coating, and an electrolytic plating film is formed in an opening portion of the plating resist film using the metal coating as a seed layer. The plating resist film is removed. The conductor layer 24 is formed that includes, for example, an electroless plating film of copper and an electrolytic plating film on the electroless plating film. In the case where a metal foil is laminated on the first resin insulating layer, the conductor layer 24 having a three-layer structure including the metal foil is formed. In FIG. 3G, the conductor layer 24 of such a three-layer structure is illustrated. At the same time when the conductor layer 24 is formed, for example, an electroless plating film is formed in the openings (23a), and by filling the openings (23a) with an electrolytic plating film, the first via conductors 25 are formed (FIG. 3G).

In the example illustrated in FIG. 3E-3J, the second build-up wiring layer is formed on the second surface (11b) side of the core substrate 11. The fourth wiring layer 42 is provided on the second surface (11b) of the core substrate 11 in the same process as the formation of the first wiring layer 22. That is, the resin insulating layer 43 of the fourth wiring layer 42 is formed on the second surface (11b) of the core substrate 11 and on the second conductor layer 13 (FIG. 3E). Openings (43a) for the fourth via conductors 45 reaching the second conductor layer 13 are formed in the resin insulating layer 43 (FIG. 3F). The conductor layer 44 having a three-layer structure, for example, is formed on the resin insulating layer 43 using a semi-additive method, and at the same time, the fourth via conductors 45 are formed in the openings (43a) (FIG. 3G). However, as in the printed wiring board 1 illustrated in FIG. 1B, it is also possible that, without having a build-up wiring layer formed on the second surface (11b) of the core substrate, the connection pads (45a) are formed on the lower surface (D) and are exposed by the opening portions (47a) of the second solder resist layer 47. In the case where a second build-up wiring layer is formed, it is preferable that the second build-up wiring layer be formed at the same time as the first build-up wiring layer.

Next, the second wiring layer 222 and the fifth wiring layer 422 are further respectively formed on the first wiring layer 22 and on the fourth wiring layer 42 (FIG. 3H). In the same process as the above-described manufacturing process in which the first wiring layer 22 and the fourth wiring layer 42 are formed, the second resin insulating layer 223, the conductor layer 224 and the second via conductors 225, as well as a fifth resin insulating layer 423, a conductor layer 424 and second via conductors 425, are formed.

The first solder resist layer 27 is formed on the second resin insulating layer 223 and on the conductor layer 224. The second solder resist layer 47 is formed on the fifth resin insulating layer 423 and on the conductor layer 424. In order to enhance adhesion between the solder resist layers (27, 47) and the resin insulating layers (223, 423), before the formation of the solder resist layers, exposed surfaces of the conductor layers (224, 424) may be subjected to a roughening treatment. A method of the roughening treatment is not particularly limited. For example, micro etching or the like is performed in which the surfaces are immersed in an organic acid-based etchant and fine irregularities are formed.

The opening portions (27a, 47a) that respective expose the pads (25a) and the pads (45a) are formed by exposure and development in the first solder resist layer 27 and the second solder resist layer 47. Also in a region above the separation film 201, an opening part (27b) of the first solder resist layer 27 is formed.

The protective films (28, 48) can be formed on the pads (25a) and the pads (45a). The protective films are films for preventing oxidation of the pads. The protective films are each formed, for example, by a Ni/Au, Ni/Pd/Au, Pd/Au or OSP film.

Next, as illustrated in FIG. 3J, by removing the separation film 201 together with the first build-up wiring layer that is formed on the separation film 201, the low-rise region (E2) is formed. For example, laser is irradiated to the upper surface (T) of the first build-up wiring layer 21 via the opening part (27b) of the first solder resist layer 27. Laser is irradiated from an upper side of the pattern 20 of the first conductor layer 12. Laser penetrates the first and second wiring layers (22, 222) of the first build-up wiring layer 21 and the separation film 201 to reach the pattern 20 of the first conductor layer 12, and a through hole is formed. An irradiation position of laser is sequentially moved along the pattern 20. The pattern 20 is formed along the peripheral edge parts of the place where the low-rise region (E2) is formed. Preferably, two ends of the pattern 20 reach an edge of the printed wiring board 1, that is, reach points near an edge of the first build-up wiring layer 21. By irradiating laser along the pattern 20, continuous through holes are formed surrounding the place where the low-rise region (E2) is formed. By irradiating laser such that the continuous through holes overlap each other, an opening is formed in a shape of a frame of which one side is an edge of the build-up wiring structure that includes the first build-up wiring layer 21.

The pattern 20 of the first conductor layer 12 functions as a laser stopper during laser irradiation. Laser is blocked by the pattern 20. Therefore, laser is not irradiated to the resin insulating layer, which becomes the exposed surface (B) of the low-rise region (E2) through a process to be described later.

In this example, the through holes are continuously formed using laser. Therefore, a damage does not occur to a wall surface 51 of a stepped portion between the high-rise region (E1) and the high-rise part (E1a) and the low-rise region (E2). Further, even when a resin insulating layer, through which laser is irradiated, contains a reinforcing material, it is possible that gaps or the like are unlikely to occur in the resin insulating layer. The separation film 201 laminated on the resin insulating layer has a good releasability from the material that forms the resin insulating layer. Since peeling from the resin insulating layer is very easy, when the separation film 201 is removed, a damage problem is unlikely to occur on the wall surface 51 and the exposed surface (B) of the low-rise region (E2). The removal process of the separation film 201 is unlikely to affect the core substrate 11 and the second build-up wiring layer 41 below the separation film 201. Further, peeling of the first build-up wiring layer 21 of the high-rise region (E1) and the high-rise part (E1a), that is, a remaining laminated portion of the build-up wiring structure that is not removed, is also unlikely to occur.

The through holes are formed using laser. Therefore, processing accuracy of the opening is high. That is, there is almost no variation in processing accuracy regarding the position of the low-rise region (E2), and product reliability in mass production is improved.

However, the opening may also be formed using a router.

A portion of the first build-up wiring layer 21 that is surrounded by the opening that is formed by laser irradiation or the like and where the low-rise region (E2) is to be formed is removed together with the separation film 201 below the portion of the first build-up wiring layer 21. The low-rise region (E2) extends to an edge of the build-up wiring structure. That is, at least one side of the low-rise region (E2) coincides with an edge of the printed wiring board 1. Therefore, by sliding the separation film 201 toward the edge of the printed wiring board 1 near the one side of the low-rise region (E2), the separation film 201 can be easily removed. The separation film 201 and the first build-up wiring layer 21 formed on the separation film 201 are removed at the same time.

The separation film 201 is not formed on the resin insulating layer 10 of the core substrate 11, but is formed, according to a desired depth of the low-rise region (E2), on any resin insulating layer and on the pattern 20 that is formed on the resin insulating layer in the place where the low-rise region (E2) is formed, such as on the first resin insulating layer 23 in the first build-up wiring layer. For example, after the formation of the separation film 201 on the first resin insulating layer 23 and on the pattern 20 that is formed on the first resin insulating layer 23, the second wiring layer 222, the third wiring layer 322 and the like are laminated on the separation film 201. Then, the first build-up wiring layer 21 on the separation film 201 in the place where the low-rise region (E2) is formed is removed together with the separation film 201. The low-rise region (E2) is formed. FIG. 5 illustrates an example in which the low-rise region (E2) is formed by laminating the separation film 201 on the first resin insulating layer 23 of the first wiring layer 22 and on the pattern 20.

The pattern 20 on the exposed surface (B) of the low-rise region (E2) may be removed by etching or the like after the formation of the low-rise region (E2). In each of FIGS. 1A, 1B and 5, a state in which the pattern 20 is removed after the formation of the low-rise region (E2) is illustrated. However, in the case where the pattern 20 is not connected to another wiring pattern in the build-up wiring structure, there is no problem for the pattern 20 to remain on the exposed surface (B) of the low-rise region (E2), without being removed. In the printed wiring board 1 of the present embodiment, a low-rise region (E2) extending to an edge of the first build-up wiring layer 21 is formed at a position in each of two directions around the high-rise region (E1) (see FIG. 1). It is also possible that a low-rise region (E2) is formed in each of three directions or four directions around the high-rise region (E1) or around the entire outer periphery of the high-rise region (E1).

According to the manufacturing method of the present embodiment, depending on an intended use of the printed wiring board 1 and a size of an electronic component to be mounted, the size of the high-rise region (E1) and the size and the depth of the low-rise region (E2) and the like in the printed wiring board 1 can be appropriately set, and the printed wiring board 1 can be manufactured based on the design.

In a printed circuit board, an external circuit layer may be laminated on an internal circuit layer, and a cavity may be formed in the external circuit layer. As in such a printed circuit board, when there is a low-rise region (cavity) surrounded by a high-rise region, it may be difficult to position with high precision a component or the like having a narrow inter-electrode pitch.

A printed wiring board according to an embodiment of the present invention includes: a core substrate that has a first surface and a second surface that is an opposite surface of the first surface; and a build-up wiring structure at least on the first surface of the core substrate, the build-up wiring structure having a first build-up wiring layer that contains at least one wiring layer that is formed by laminating a resin insulating layer and a conductor layer. In the build-up wiring structure, a high-rise region and a low-rise region are formed. The high-rise region has electrodes for connecting to an electronic component and has a high height in a lamination direction. The low-rise region is formed in each of at least two directions around the high-rise region and has a height in the lamination direction lower than that of the high-rise region. The low-rise region extends to an edge of the build-up wiring structure.

A method for manufacturing a printed wiring board according to another embodiment of the present invention includes: preparing a core substrate that has a first surface and a second surface that is an opposite surface of the first surface, and has a first conductor layer and a second conductor layer respectively on the first surface and the second surface; forming a build-up wiring structure at least on the first surface of the core substrate, the build-up wiring structure having a first build-up wiring layer that contains at least one wiring layer that is formed by laminating a resin insulating layer and a conductor layer; and forming a high-rise region and a low-rise region in the build-up wiring structure by removing a portion of the first build-up wiring layer, the high-rise region having a high height in a lamination direction, and the low-rise region having a height in the lamination direction lower than that of the high-rise region. The forming of the build-up wiring structure includes forming electrodes for connecting to an electronic component in a middle portion of the first build-up wiring layer, the middle portion becoming the high-rise region. The low-rise region is formed at a position in each of at least two directions around the high-rise region and extends to an edge of the build-up wiring structure.

In a printed wiring board according to an embodiment of the present invention, electronic components can be mounted to the high-rise region and the low-rise region. Since an electronic component having a thicker thickness can be mounted in the low-rise region, a thickness of the printed wiring board after the mounting can be suppressed.

In a printed wiring board according to an embodiment of the present invention, an component or the like having a narrow inter-electrode pitch can be suitably positioned with high precision both in the high-rise region and in the low-rise region.

In a method for manufacturing a printed wiring board according to an embodiment of the present invention, a separation film is removed together with a portion of the first build-up wiring layer in a place where the low-rise region is formed. Lamination of the separation film can be performed as a part of a lamination process of the first build-up wiring layer. Further, removal of the first build-up wiring layer on the separation film can also be easily performed at the same time when the separation film is removed. It is expected that the printed wiring board can be easily manufactured.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a core substrate; and
a first build-up wiring layer formed on the core substrate and comprising a wiring layer such that the wiring layer comprises a resin insulating layer and a conductor layer laminated on the resin insulating layer,
wherein the first build-up wiring layer is formed on a first surface of the core substrate such that the first build-up wiring layer forms a high-rise region and a low-rise 10 region with respect to a lamination direction, the first build-up wiring layer comprises a plurality of electrodes positioned to connect an electronic component to the first build-up wiring layer, and the first build-up wiring layer is formed such that the low-rise region is extending in at least two directions from the high-rise region to edges of the core substrate.

2. A printed wiring board according to claim 1, further comprising:
a second build-up wiring layer formed on a second surface of the core substrate on an opposite side with respect to the first surface such that the second build-up wiring layer includes a wiring layer comprising a resin insulating layer and a conductor layer laminated on the resin insulating layer.

3. A printed wiring board according to claim 1, wherein the first build-up wiring layer is formed on the first surface of the core substrate such that the low-rise region is formed in a removed portion of the first build-up wiring layer.

4. A printed wiring board according to claim 1, wherein the first build-up wiring layer is formed on the first surface of the core substrate such that the low-rise region comprises a plurality of separate low-rise portions.

5. A printed wiring board according to claim 1, wherein the first build-up wiring layer is formed on the first surface of the core substrate such that the low-rise region comprises a pair of opposing low-rise portions sandwiching the high-rise region.

6. A printed wiring board according to claim 1, wherein the first build-up wiring layer is formed on the first surface of the core substrate such that the low-rise region comprises a first pair of opposing low-rise portions sandwiching the high-rise region and a second pair of opposing low-rise portions sandwiching the high-rise region and separated by 90 degree from the first pair of opposing low-rise portions.

7. A printed wiring board according to claim 1, wherein the first build-up wiring layer is formed on the first surface of the core substrate such that the low-rise region is surrounding an entire periphery of the high-rise region.

8. A printed wiring board according to claim 1, wherein the first build-up wiring layer is formed on the first surface of the core substrate such that the low-rise region has an exposed surface formed on a plane of an interface between the first build-up wiring layer and the first surface of the core substrate.

9. A printed wiring board according to claim 1, further comprising:
a wiring layer formed in the low-rise region such that the plurality of electrodes in the first build-up wiring layer is connected to the wiring layer in the low-rise region.

10. A printed wiring board according to claim 1, wherein the first build-up wiring layer is formed on the first surface of the core substrate such that the low-rise region has an exposed surface on which a pad for connecting an external component is not formed.

11. A printed wiring board according to claim 1, wherein the first build-up wiring layer comprises a plurality of resin insulating layers and a plurality of conductor layers.

12. A printed wiring board according to claim 1, wherein the first build-up wiring layer comprises a conductor layer formed on an outermost surface side of first build-up wiring layer, and each of the electrodes has a protruding portion protruding with respect to the conductor layer formed on the outermost surface side of first build-up wiring layer.

13. A method for manufacturing a printed wiring board, comprising:
preparing a core substrate comprising a first conductor layer and a second conductor layer on an opposite side with respect to the first conductor layer;
forming on a first surface of the core substrate a first build-up wiring layer comprising a wiring layer such that the wiring layer comprises a resin insulating layer and a conductor layer laminated on the resin insulating layer; and
removing at least one portion of the first build-up wiring layer such that the first build-up wiring layer forms a high-rise region and a low-rise region with respect to a lamination direction,
wherein the forming of the first build-up wiring layer comprises forming a plurality of electrodes such that the plurality of electrodes is positioned to connect an electronic component to the first build-up wiring layer, and the removing of at least one portion of the first build-up wiring layer comprises forming the low-rise region such that the low-rise region is extending in at least two directions from the high-rise region to edges of the core substrate.

14. A method for manufacturing a printed wiring board according to claim 13, further comprising:
laminating a separation film at the portion of the first build-up wiring layer to be removed,
wherein the removing of the portion of the first build-up wiring layer comprises cutting the first build-up wiring layer to the separation film such that the portion of the first build-up wiring layer is cut in a frame shape at a position of the low-rise region.

15. A method for manufacturing a printed wiring board according to claim 14, wherein the laminating of the separation film comprises laminating the separation film at a position between the core substrate and the first build-up wiring layer.

16. A method for manufacturing a printed wiring board according to claim 14, wherein the forming of the first build-up wiring layer comprises forming the first build-up wiring layer such that the first build-up wiring layer includes the wiring layer in a plurality, and the laminating of the separation film comprises laminating the separation film at a position between the plurality of wiring layers.

17. A method for manufacturing a printed wiring board according to claim 14, further comprising:
laminating a metal foil at the portion of the first build-up wiring layer to be removed such that the separation film is to be laminated on the metal foil.

18. A method for manufacturing a printed wiring board according to claim 13, wherein the removing of at least one portion of the first build-up wiring layer comprises irradiating laser upon the first build-up wiring layer such that at least one portion of the first build-up wiring layer is cut out from the first build-up wiring layer.

19. A method for manufacturing a printed wiring board according to claim 13, further comprising:
forming a solder resist layer on a surface of the first build-up wiring layer; and
forming a plurality of opening portion in the solder resist layer such that the plurality of opening portions exposes the plurality of electrodes, respectively,
wherein the forming of the first build-up wiring layer comprising forming a via conductor penetrating through the resin insulating layer and connected to the conductor layer.

20. A method for manufacturing a printed wiring board according to claim 13, further comprising:
forming a second build-up wiring layer on a second surface of the core substrate on an opposite side with respect to the first surface such that the second build-up wiring layer includes a plurality of pads and a wiring layer comprising a resin insulating layer and a conductor layer laminated on the resin insulating layer;
forming a solder resist layer on a surface of second build-up wiring layer; and
forming a plurality of opening portions in the solder resist layer such that the plurality of opening portions exposes the plurality of pads in the second build-up wiring layer, respectively.
